(19) United States
(12) Patent Application Publication
(10) Pub. No.: US 2018/0212001 A1
(43) Pub. Date: Jul. 26, 2018

(54) PIXEL STRUCTURE, FABRICATION METHOD THEREOF, DISPLAY PANEL, AND DISPLAY APPARATUS

(71) Applicants: BOE TECHNOLOGY GROUP CO., LTD., Beijing (CN); CHONGQING BOE OPTOELECTRONICS TECHNOLOGY CO., LTD., Chongqing (CN)

(72) Inventors: Yajie BAI, Beijing (CN); Zhuo XU, Beijing (CN); Xiaoyuan WANG, Beijing (CN); Jaikwang KIM, Beijing (CN)

(73) Assignees: BOE TECHNOLOGY GROUP CO., LTD., Beijing (CN); CHONGQING BOE OPTOELECTRONICS TECHNOLOGY CO., LTD., Chongqing (CN)

(21) Appl. No.: 15/326,154

(22) PCT Filed: May 20, 2016
(86) PCT No.: PCT/CN2016/082894

§ 371 Date: Jan. 13, 2017

(30) Foreign Application Priority Data
Oct. 10, 2015 (CN) 201510652459.4

(51) Int. Cl. H01L 27/32; H01L 51/56

(52) U.S. Cl. CPC H01L 27/3218; H01L 51/56; H01L 27/3213

(57) ABSTRACT

The present disclosure provides a pixel structure and a fabricating method thereof, as well as a display panel and a display apparatus. The pixel structure includes a plurality of pairs of pixels in a matrix having rows and columns; each pixel is shaped as a right triangle and corresponds to one of four different colors; each pair of pixels is at an intersection between a row and a column and comprises two pixels of different colors; and two pairs of pixels at two neighboring intersections along a direction of the rows or along a direction of the columns comprise four pixels of different colors. Each pair of pixels can have a combined shape of a rectangle, which can form a virtual pixel unit. Adjacent four pixels of four different colors have a combined shape of diamond, which can form a physical pixel unit.

### CROSS-REFERENCE TO RELATED APPLICATION

The present application claims priority to Chinese Patent Application No. 201510652459.4 filed on Oct. 10, 2015, the disclosure of which is hereby incorporated by reference in its entirety.

### TECHNICAL FIELD

The present disclosure relates generally to the field of display technology, and more specifically to a pixel structure and its fabrication method, and a display panel and a display apparatus comprising the pixel picture.

### BACKGROUND

A display panel is typically configured to comprise three pixels in each of its pixel units. The three pixels correspond to the three primary colors including red, green, and blue. When a particular color is to be displayed, the gray values of each of the red pixel (R), the green pixel (G), and the blue pixel (B) are adjusted to display that particular color from a combination of the R, G, B. The configuration for the array of pixels is associated with the resolution provided by the display panel. Pixel units are typically arranged in straight lines, as shown in FIG. 1.

To increase the light-emitting efficiency, and/or to improve the display visual effects, display panels having four-color pixel units have been developed. For example, a white pixel or a yellow pixel can be included in addition to the RGB pixels, so as to produce a particular color by combining these four pixels.

### SUMMARY

The present disclosure provides a pixel structure and a fabrication method thereof, as well as a display panel and a display apparatus. The issues in conventional pixel structures, such as not being compatible in simultaneously supporting general displays and virtual displays, can be solved according to some embodiments disclosed herein.

In an aspect, a pixel structure is provided in the disclosure. The pixel structure includes a plurality of pairs of pixels in a matrix having rows and columns; each pixel is shaped as a right triangle and corresponds to one of four different colors; each pair of pixels is at an intersection between a row and a column and comprises two pixels of different colors; and two pairs of pixels at two neighboring intersections along a direction of the rows or along a direction of the columns comprise four pixels of different colors.

In some embodiments of the pixel structure, each pair of pixels can have a combined shape of a rectangle, and can have a combined shape of a square. The combined shape of a rectangle can form a virtual pixel unit. In some embodiments, adjacent four pixels of four different colors can have a combined shape of diamond, and the four pixels of four different colors selects from four pairs of pixels at four intersections between two neighboring rows and two neighboring columns. The combined shape of diamond can form a physical pixel unit.

In some embodiments of the pixel structure, each pixel can be shaped as an isosceles right triangle, and each pixel can have a same shape and a same size. The four different colors can include red, green, blue and white in some embodiments, and can include red, green, blue and yellow in some other embodiments.

In another aspect, this disclosure provides a display panel, which comprises the pixel structure as described above.

In yet another aspect, this disclosure provides a display apparatus, which comprises the display panel as described above. In some embodiments, the display apparatus may be a liquid crystal display (LCD) apparatus, a light-emitting diode (LED) apparatus, an organic LED (OLED) apparatus, an organic electroluminescent display apparatus, a cathode ray tube (CRT) apparatus, a plasma display apparatus, an e-paper apparatus, or an electroluminescent apparatus.

In yet another aspect, this disclosure provides a method for fabricating a pixel structure as described above. The method comprises utilizing at least one mask to form color resist pattern for pixels corresponding to at least two of the four different colors in the pixel structure.

In some embodiments, the pixel structure is in a rectangle active display region of a display panel. Two ways of fabrication is possible, depending on if there is a pixel corresponding to a white color. In embodiments where none of the four different colors is white color, the method can include: utilizing a first mask to form a first color resist pattern for pixels corresponding to a first color; utilizing the first mask to form a second color resist pattern for pixels corresponding to a second color after rotating the first mask for 180°; utilizing a second mask to form a third color resist pattern for pixels corresponding to a third color; and utilizing the second mask to form a fourth color resist pattern for pixels corresponding to a fourth color after rotating the second mask for 180°. In embodiments where the four different colors include three non-white colors and a white color, the method includes: utilizing a first mask to form a first color resist pattern for pixels corresponding to a first of the three non-white colors; utilizing the first mask to form a second color resist pattern for pixels corresponding to a second of the three non-white colors after rotating the first mask for 180°; and utilizing a second mask to form a third color resist pattern for pixels corresponding to a third of the three different colors.

In some embodiments, the pixel structure is in a square active display region of a display panel. Two ways of fabrication is possible, depending on if there is a pixel corresponding to a white color. In embodiments where none of the four different colors is white color, the method can include: utilizing a first mask to form a first color resist pattern for pixels corresponding to a first color; utilizing the first mask to form a second color resist pattern for pixels corresponding to a second color after rotating the first mask for 90°; utilizing the first mask to form a third color resist pattern for pixels corresponding to a third color after rotating the first mask for 180°; and utilizing the first mask to form a fourth color resist pattern for pixels corresponding to a fourth color after rotating the first mask for 270°. In embodiments where the four different colors comprise three non-white colors and a white color, the method includes: utilizing a first mask to form a first color resist pattern for pixels corresponding to a first of the three non-white colors; utilizing the first mask to form a second color resist pattern for pixels corresponding to a second of the three non-white colors after rotating the first mask for 90°; and utilizing the first mask to form a third color resist pattern for pixels corresponding to a third of the three non-white colors after rotating the first mask for 180°.

At least some of the embodiments disclosed herein can have one or more of the following advantages: the present disclosure provides a pixel structure and a fabricating method thereof, as well as a display panel and a display apparatus. The pixel structure includes four different types of pixels corresponding to four different colors. Because each pixel is shaped as a right triangle, every two different pixels can form a virtual pixel unit having a shape of rectangle; all the virtual pixel units are arranged in a matrix having rows and columns, and the pixels contained in two neighboring virtual pixel units correspond to different colors; every four pixels corresponding to four different colors are arranged to have their respective right angles gathering at one point, which together form a physical pixel unit that has a shape of a diamond. The shape of the physical pixel units and the shape of the virtual pixel units are both rectangular, thus allowing the pixel structure to be compatible to support both general displays and virtual displays; thereby pictures with a high level of uniformity can be realized for high-resolution virtual displays by means of the virtual pixel units, and for low-resolution general displays by means of the physical (general) pixel units, thus resulting in balanced visual effects.

Other embodiments and implementations may become apparent in view of the following descriptions and the attached drawings.

### BRIEF DESCRIPTION OF DRAWINGS

To more clearly illustrate some of the embodiments, the following is a brief description of the drawings. The drawings in the following descriptions are only illustrative of some embodiments. For those of ordinary skill in the art, other drawings of other embodiments can become apparent based on these drawings.

FIG. 1 is a schematic diagram of a conventional pixel structure, wherein each pixel unit comprises three types of pixels corresponding to the three primary colors R, G, B.

FIG. 2 is a schematic diagram of a repeating pixel unit in a conventional virtual pixel structure.

FIG. 3 is a schematic diagram of a pixel unit according to some embodiments of the disclosure.

FIG. 4A is a schematic diagram of a pixel unit according to a first embodiment.

FIG. 4B is a schematic diagram of a pixel unit according to a second embodiment.

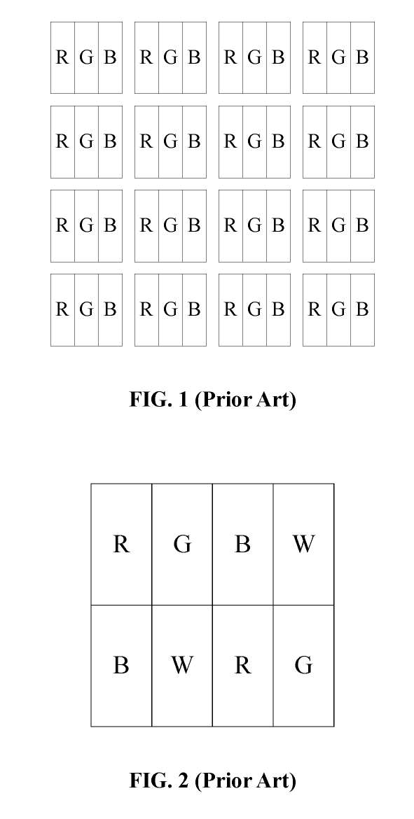

### DETAILED DESCRIPTION

In the following, with reference to the drawings of various embodiments disclosed herein, the various aspects of the disclosure, including a pixel structure and a fabrication method thereof, as well as a display panel and a display apparatus, will be described in detail. It is noted that the described embodiments are merely a portion but not all of the embodiments of the invention. Based on the described embodiments of the invention, those ordinarily skilled in the art can obtain other embodiment(s), without any inventive work, which come(s) within the scope sought for protection by the invention.

A four-color display panel that has four pixels in each of its pixel units typically has a lower resolution than a three-color display panel with three-pixel units. In order to solve this issue, a virtual display technology, or Pentile technology, has been developed. Pentile technology is based on the observation that the resolution for brightness is several folds higher than the resolution for chroma in human visual system. By borrowing neighboring pixels, also referred to as rendering pixels, or color diffusion, and employing corresponding algorithms, the Pentile technology can achieve a higher resolution for current display technologies.

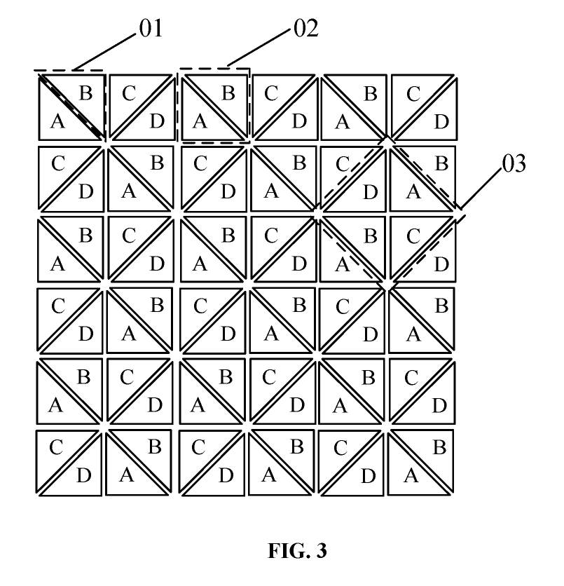

For example, in the virtual pixel structure as shown in FIG. 2, the virtual display is realized by having 2×8 pixels shaped as straight lines to form a repeating unit. However, a current virtual display that employs the pixel structure as shown in FIG. 2 results in a severe loss of balance in display ratios. As such, current virtual pixel unit design is incompatible with a display technology that does not employ the Pentile technology, and current virtual pixel is unable to combine with general physical pixels for display.

In an aspect, the present disclosure provides a pixel structure that can overcome the deficiencies in the conventional technologies. As illustrated in FIG. 3, a pixel structure according to some embodiments includes a plurality of pixels 01, each having a shape of a right triangle. The plurality of pixels can include four different types of pixels, each corresponding to one of four different colors, labeled as A, B, C and D in FIG. 3. Each two pixels 01 corresponding to two different colors and having a combined shape of a rectangle form a virtual pixel unit 02. All the virtual pixel units 02 are arranged in a matrix having rows and columns, wherein the four pixels 01 contained in two neighboring virtual pixel units 02 correspond to four different colors. Four neighboring pixels 01, corresponding to four different colors and aligned to have their respective right angles facing each other and have their respective hypotenuses forming a shape of diamond, form a physical pixel unit 03.

In the pixel structure as described above, because each individual pixel is shaped as a right triangle, every two individual pixels corresponding to two different colors can be combined to form a virtual pixel unit with a shape of a rectangle, and every four individual pixels corresponding to four different colors can be arranged to have their respective right angles facing each other and have their respective hypotenuses forming a shape of diamond to form a physical pixel unit. The diamond shape can be regarded as a tilted rectangle. Because the shape of the physical pixel units and the shape of the virtual pixel units are both rectangular, such a pixel structure can be compatible to support both general displays and virtual displays. Pictures with a high level of uniformity can be realized for high-resolution virtual displays by means of the virtual pixel units. Meanwhile, low-resolution general displays employing the physical (general) pixel units can also be achieved. As such, balanced visual effects can be realized.

It is noted that in the pixel structure as described above, a virtual pixel unit contains two pixels, which are by themselves unable to combinatorially produce all of the colors due to the fact that at least three colors are required for the generation of all type of colors. Therefore, in practice, a virtual pixel unit may need to borrow another pixel in a neighboring virtual pixel unit with a different color to comprise three different colors. The neighboring virtual pixel unit can be a virtual pixel unit in a neighboring row, or a virtual pixel unit in a neighboring column, depending on different ways to drive the display. As such, to realize virtual displays, the virtual pixel unit either in a neighboring row or in a neighboring column can be configured to correspond to different colors for the pixels contained therein.

In some implementations, the pixel structure described above can be configured to have a shape of an isosceles right triangle, as illustrated in FIG. 3. This ensures that the virtual pixel units each comprising two pixels and the physical pixel units each comprising four pixels are both shaped as squares. Squared-shaped pixel units can result in improved visual effects.

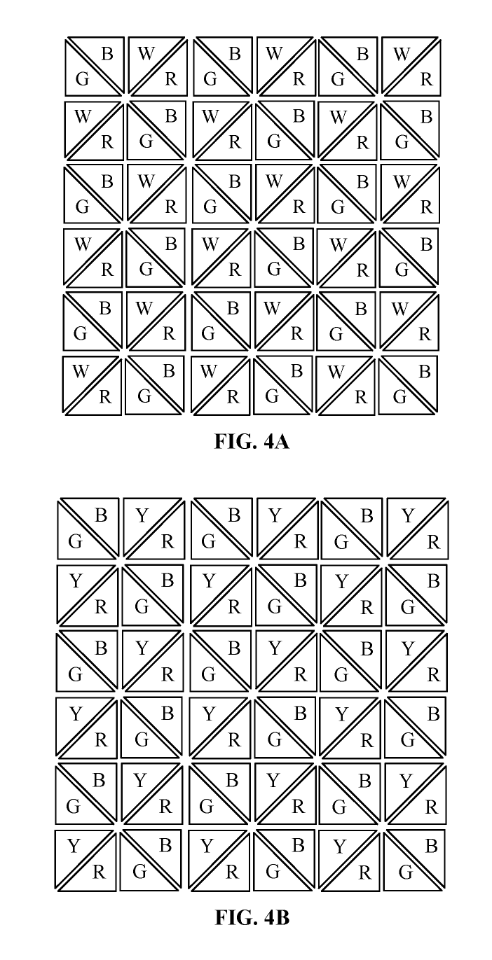

In some implementations, the four different colors for the four different types of pixels contained in the pixel structure as described above can be arranged differently, depending on different display quality requirements. In situations where it is preferred to have increased display brightness and reduced energy consumption, the four different types of pixels in a pixel structure can include a red pixel R, a green pixel G, a blue pixel B, and a white pixel W, as illustrated in FIG. 4A. In situations where the color gamut needs to be increased to improve the display quality, the four different types of pixels in a pixel structure can include a red pixel R, a green pixel G, a blue pixel B, and a yellow pixel Y, as illustrated in FIG. 4B.

It is noted that the pixel structure as described above can be applied in a liquid crystal display (LCD), a light-emitting diode (LED) display, an organic LED(OLED) display, or other types of display panels. The embodiments are not limited by these examples.

Specifically, in embodiments where the pixel structure as described above is applied in an OLED display, each individual pixel contained in the pixel structure can be configured to emit light with a same color, and more specifically the light emitting layer can emit light with the same color. Alternatively, each individual pixel contained in the pixel structure can be provided with color filters with a same color. Various embodiments are not limited by these examples.

In another aspect, the disclosure also provides a method for fabricating the pixel structure described above. The method includes the step of utilizing a mask to respectively form color resist patterns for at least two different types of pixels corresponding to two different colors in a pixel structure. By repeating the process of forming color resist patterns for at least two colors, this method can save the number of masks used, thereby resulting in a simplified fabrication process and reduced fabrication cost.

In embodiments where the pixel structure as described above is applied in LCDs, the color resist patterns for pixels can be realized using color filters. For example, a method of fabricating a pixel structure can include: utilizing a mask to respectively form color filters for at least two colors.

In some other embodiments where the pixel structure as described above is applied in OLEDs, the color resist patterns can be realized using color filters, and specifically the method for fabricating the pixel structure can comprise: utilizing a mask to respectively form color filters for at least two colors. Alternatively, the color resist patterns can be realized by configuring the light-emitting layers to emit light of different colors. For example, the method for fabricating the pixel structure can comprise: utilizing a mask to respectively form light-emitting layers for light of at least two colors.

In some implementations, different number of masks can be used for fabricating the color resist patterns for all the colors in the pixel structure, depending on the shapes of the active display region of a specific display panel that employs the pixel structure.

### Embodiment 1

If the pixel structure as described above is configured to be applied in a rectangle active display region of a display panel, one mask can be utilized to form the color resist pattern for two types of pixels that correspond to two different colors. Because a pixel structure includes a total of four types of pixels corresponding to four different colors, two masks can thus be used to form all color resist patterns. Specifically, the method comprises the following steps:

Step a): utilizing a first mask to form a first color resist pattern for a first type of pixels;

Step b): utilizing the first mask to form a second color resist pattern for a second type of pixels after rotating the first mask for 180°;

Step c): utilizing a second mask to form a third color resist pattern for a third type of pixels;

Step d): utilizing the second mask to form a fourth color resist pattern for a fourth type of pixels after rotating the second mask for 180°.

It is noted that for both LCD and OLED, if the pixel structure as described above contains a white pixel, the step for forming white color resist patterns can be optional and can be skipped. This is because when forming color resist patterns via color filers, the white pixel in LCDs can be directly derived from backlight modules while the white pixel in OLEDs can be realized through the light emitted from the light-emission layer.

As such, if the step of forming white color resist patterns is skipped in Embodiment 1, the simplified method comprises the following steps:

Step a): utilizing a first mask to form a first color resist pattern for a first type of pixels;

Step b): utilizing the first mask to form a second color resist pattern for a second type of pixels after rotating the first mask for 180°;

Step c): utilizing a second mask to form a third color resist pattern for a third type of pixels.

### Embodiment 2

If the pixel structure as described above is configured to be applied in a square active display region of a display panel, one mask can be utilized to form color resist patterns for three or four types of pixels in a pixel structure. In cases where a pixel structure comprises a white pixel, one mask can be utilized to form the color resist patterns for three types of pixels in the pixel structure because color resist patterning is not required by the white pixel. Since the pixel structure includes a total of four different types of pixels, one mask can be used to form all color resist patterns, by rotating the mask by 90° each time after a previous color resist pattern has been formed.

Specifically, if the color resist pattern is to be formed for four different types of pixels, the method comprises the following steps:

Step i): utilizing a first mask to form a first color resist pattern for a first type of pixels;

Step ii): utilizing the first mask to form a second color resist pattern for a second type of pixels after rotating the first mask for 90°;

Step iii): utilizing the first mask to form a third color resist pattern for a third type of pixels after rotating the first mask for 180°;

Step iv): utilizing the first mask to form a fourth color resist pattern for a fourth type of pixels after rotating the first mask for 270°.

Specifically, if color resist patterns are to be formed for three different types of pixels, the method comprises the following steps:

Step i): utilizing a first mask to form a first color resist pattern for a first type of pixels;

Step ii): utilizing the first mask to form a second color resist pattern for a second type of pixels after rotating the first mask for 90°;

Step iii): utilizing the first mask to form a third color resist pattern for a third type of pixels after rotating the first mask for 180°.

Based on the same design, the disclosure provides a display panel, which includes the pixel structure as described above. The various embodiments of the pixel structure can be applied for the various embodiments of the display panel.

In another aspect, the present disclosure provides a display apparatus, which includes the display panel as described above. The various embodiments of the display panel can be applied for the various embodiments of the display apparatus.

In some implementations, the display apparatus as described above can be an LCD apparatus, a LED apparatus, an OLED apparatus, an organic electroluminescent display apparatus, a cathode ray tube (CRT) display apparatus, a plasma display apparatus, an e-paper display apparatus, or an electroluminescent display. The embodiments are not limited by these examples.

The present disclosure provides a pixel structure and a fabricating method thereof, as well as a display panel and a display apparatus. The pixel structure includes four different types of pixels corresponding to four different colors. Because each pixel is shaped as a right triangle, every two different pixels can form a virtual pixel unit having a shape of rectangle; all the virtual pixel units are arranged in a matrix having rows and columns, and the pixels contained in two neighboring virtual pixel units correspond to different colors; every four pixels corresponding to four different colors are arranged to have their respective right angles gathering at one point, which together form a physical pixel unit that has a shape of a diamond. The shape of the physical pixel units and the shape of the virtual pixel units are both rectangular, thus allowing the pixel structure to be compatible to support both general displays and virtual displays; thereby pictures with a high level of uniformity can be realized for high-resolution virtual displays by means of the virtual pixel units, and for low-resolution general displays by means of the physical (general) pixel units, thus resulting in balanced visual effects.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A pixel structure in a display panel, comprising a plurality of pairs of pixels in a matrix having rows and columns, wherein:
each pixel is shaped as a right triangle and corresponds to one of four different colors;
each pair of pixels is at an intersection between a row and a column and comprises two pixels of different colors; and
two pairs of pixels at two neighboring intersections along a direction of the rows or along a direction of the columns comprise four pixels of different colors.

2. The pixel structure of claim 1, wherein each pair of pixels has a combined shape of a rectangle.

3. The pixel structure of claim 2, wherein each pair of pixels has a combined shape of a square.

4. The pixel structure of claim 2, wherein the combined shape of a rectangle forms a virtual pixel unit.

5. The pixel structure of claim 1, wherein adjacent four pixels of four different colors have a combined shape of diamond.

6. The pixel structure of claim 5, wherein the combined shape of diamond forms a physical pixel unit.

7. The pixel structure of claim 1, wherein each pixel is shaped as an isosceles right triangle.

8. The pixel structure of claim 1, wherein each pixel has a same shape and a same size.

9. The pixel structure of claim 1, wherein the four different colors comprise red, green, blue and white.

10. The pixel structure of claim 1, wherein the four different colors comprise red, green, blue and yellow.

11. (canceled)

12. A display apparatus, comprising a display panel, wherein the display panel comprises the pixel structure according to claim 1.

13. The display apparatus of claim 12, wherein the display apparatus is one of a liquid crystal display (LCD) apparatus, a light-emitting diode (LED) apparatus, an organic LED (OLED) apparatus, an organic electroluminescent display apparatus, a cathode ray tube (CRT) apparatus, a plasma display apparatus, an e-paper apparatus, and an electroluminescent apparatus.

14. A method of fabricating the pixel structure according to claim 1, the method comprising: utilizing one mask to form color resist pattern for pixels corresponding to at least two of the four different colors in the pixel structure.

15. The method according to claim 14, wherein the pixel structure is in a rectangle active display region of a display panel.

16. The method according to claim 15, wherein none of the four different colors is white color, the method comprising:
utilizing a first mask to form a first color resist pattern for pixels corresponding to a first color;
utilizing the first mask to form a second color resist pattern for pixels corresponding to a second color after rotating the first mask for 180°;
utilizing a second mask to form a third color resist pattern for pixels corresponding to a third color; and
utilizing the second mask to form a fourth color resist pattern for pixels corresponding to a fourth color after rotating the second mask for 180°.

17. The method according to claim 15, wherein the four different colors comprise three non-white colors and a white color, the method comprising:
utilizing a first mask to form a first color resist pattern for pixels corresponding to a first of the three non-white colors;
utilizing the first mask to form a second color resist pattern for pixels corresponding to a second of the three non-white colors after rotating the first mask for 180°; and
utilizing a second mask to form a third color resist pattern for pixels corresponding to a third of the three different colors.

18. The method according to claim 14, the pixel structure is in a square active display region of a display panel.

19. The method according to claim 18, wherein none of the four different colors is white color, the method comprising:
utilizing a first mask to form a first color resist pattern for pixels corresponding to a first color;
utilizing the first mask to form a second color resist pattern for pixels corresponding to a second color after rotating the first mask for 90°;
utilizing the first mask to form a third color resist pattern for pixels corresponding to a third color after rotating the first mask for 180°; and
utilizing the first mask to form a fourth color resist pattern for pixels corresponding to a fourth color after rotating the first mask for 270°.

20. The method according to claim 18, wherein the four different colors comprise three non-white colors and a white color, the method comprising:
utilizing a first mask to form a first color resist pattern for pixels corresponding to a first of the three non-white colors;
utilizing the first mask to form a second color resist pattern for pixels corresponding to a second of the three non-white colors after rotating the first mask for 90°; and
utilizing the first mask to form a third color resist pattern for pixels corresponding to a third of the three non-white colors after rotating the first mask for 180°.
